(19) United States
(12) Patent Application Publication
(10) Pub. No.: US 2008/0239680 A1
(43) Pub. Date: Oct. 2, 2008

(54) METHOD OF FORMING BURIED WIRING LINES, AND SUBSTRATE AND DISPLAY DEVICE USING THE SAME

(75) Inventor: Kyounei YASUDA, Kanagawa (JP)

Correspondence Address: YOUNG & THOMPSON, 209 Madison Street, Suite 500, ALEXANDRIA, VA, 22314, US

(73) Assignee: NEC LCD TECHNOLOGIES, LTD., Kanagawa (JP)

(21) Appl. No.: 12/059,765

(22) Filed: Mar. 31, 2008

(30) Foreign Application Priority Data
Mar. 30, 2007 (JP) 2007-090928

(51) Int. Cl. H05K 3/40; H05K 1/11

(52) U.S. Cl. 361/748; 29/846

(57) ABSTRACT

An method of forming buried wiring lines makes it possible not to limit usable materials for an insulative plate to those having excellent heat resistance and to improve the corrosion resistance of the terminals provided for the buried wiring lines. The surface of an insulative plate is selectively etched using a mask formed on the surface, thereby forming grooves in the surface. A metallic nanoparticle ink is placed over the whole surface of the plate to fill the grooves with the ink, where the mask is being left. The ink is heated for preliminary curing to form a metallic nanoparticle ink film. The part of the film placed on the mask is selectively removed by detaching the mask, thereby leaving the remainder of the film in the grooves. The remaining film in the grooves is heated for main curing, thereby forming desired buried wiring lines.

### BACKGROUND OF THE INVENTION

1. Field of the Invention

The present invention relates to a method of forming buried wiring lines, a substrate for a display device including the buried wiring lines, and a display device including the substrate. More particularly, the present invention relates to a method of forming wiring lines buried in grooves formed in the surface of an insulative plate (i.e., buried wiring lines), a substrate for a display device using the method or the buried wiring lines thus formed, and a display device using the said substrate. The present invention is preferably applied to large area, high definition, and high aperture-ratio of Liquid-Crystal Display (LCD) devices using Thin-Film Transistors (TFTs).

2. Description of the Related Art

In recent years, the LCD device has been extensively used as a high-resolution display device. The LCD device comprises a substrate on which switching elements such as Thin-Film Transistors (TFTs) are formed (which will be termed the “TFT substrate” below), another substrate on which a color filter and a black matrix are formed (which will be termed the “opposite substrate” below), and a liquid crystal layer sandwiched between the TFT substrate and the opposite substrate. An electric field is applied across the electrodes formed on the TFT substrate and those formed on the opposite substrate, or across the electrodes formed on the TFT substrate and the other electrodes formed on the said TFT substrate, thereby changing the alignment direction of the liquid crystal molecules in the liquid crystal layer. In this way, the amount of the transmitted light in each pixel is controlled to display desired characters, images, and so on.

On the TFT substrate, for example, gate lines (or scanning lines), drain lines (or signal lines), and common lines are formed in the matrix form, where gate input terminals, drain input terminals, and common electrode input terminals are respectively formed at the ends of the gate lines, the drain lines, and the common lines. These input terminals are provided for electrical connection to driving circuit elements mounted outside the TFT substrate. Electrical interconnection of the gate lines, the drain lines, and the common lines to the external driving circuit elements is carried out using the TAB (Tape-Automated Bonding) technique or the like.

In this specification, conductive lines used for electrical interconnection, such as the gate lines, the drain lines, and the common lines exemplified as above, may be generically termed “wiring lines”.

The active-matrix addressing LCD device using the TFTs as the switching elements has an advantage that the contrast and the response speed do not deteriorate even if the number of the scanning lines is increased. Therefore, larger-sized, high-quality display devices can be realized with the active-matrix addressing LCD device. However, if the size of the LCD device becomes larger, the above-described wiring lines will be longer and the wiring resistance will increase accordingly. As a result, the display quality will deteriorate due to the delay of the signals flowing through the wiring lines.

In addition, recently, there has been a demand to further increase the pixel density and to further raise the aperture ratio and therefore, the wiring lines need to be narrowed. However, the narrowing of the wiring lines induces the rising of the electrical resistance similar to the case where the wiring lines are made longer. This leads to display quality degradation due to signal transmission delay also.

One of the known methods for preventing such the wiring resistance increase as above that leads to the display quality deterioration is to increase the thickness of the wiring lines. An example of this method will be explained below with reference to FIGS. 1A to 1C.

FIG. 1A is a partial cross-sectional view of the TFT section of a TFT substrate used for a prior-art LCD device, where the gate lines are thickened. FIG. 1B is a partial cross-sectional view of the gate input terminal section of the TFT substrate shown in FIG. 1A. FIG. 1C is a partial cross-sectional view of the intersecting section of the gate lines and the drain lines of the TFT substrate shown in FIG. 1A. FIGS. 1A to 1C show the structures corresponding to one of the pixels arranged in a matrix array on the TFT substrate, respectively.

Gate electrodes 102 and gate lines 102a having a predetermined pattern are disposed on the surface of an insulative plate 101. The gate electrodes 102 and the gate lines 102a are covered with a transparent gate insulating film 103 formed on the surface of the plate 101. The gate electrodes 102 and the corresponding gate lines 102a, which are respectively formed in such a way as to be united with each other by patterning the same conductive film, are electrically interconnected to each other. The gate lines 102a extend linearly along a predetermined direction in the form of stripes (see FIG. 1B). The gate electrodes 102 are respectively formed to protrude to the corresponding TFT sections along a direction perpendicular to the gate lines 102a (see FIG. 1A). The pattern which is applied to the gate electrodes 102 and the gate lines 102a will be termed the “gate wiring pattern” below. The thickness of the gate electrodes 102 and the gate lines 102a is larger than that of ordinary LCD devices.

As shown in FIG. 1A, patterned semiconductor films 104 each having an island-like shape are disposed on the gate insulating film 103 at the positions overlapped with the corresponding gate electrodes 102. A pair of n⁺-type patterned semiconductor films 105 for ohmic contacts is disposed on each semiconductor film 104 at both sides thereof except for the region right above the middle part of a corresponding one of the gate electrodes 102. A pair of source electrode 106 and a drain electrode 107 is formed on a corresponding one of the pairs of n⁺-type semiconductor films 105.

Drain lines 107a, which are formed by patterning the same conductive film as that for the source and drain electrodes 106 and 107, are united with the drain electrodes 107 (see FIG. 1C). The drain lines 107a extend linearly along a direction perpendicular to the running direction of the gate lines 102a in the form of stripes. The drain electrodes 107 are formed to protrude to the corresponding TFT sections along a direction perpendicular to the drain lines 107a.

A passivation film 108 is formed on the gate insulating film 103 to cover the source and drain electrodes 106 and 107 and the drain lines 107a. The passivation film 108 is in contact with the source and drain electrodes 106 and 107, the drain lines 107a, and the exposed parts of the gate insulating film 103 (see FIGS. 1A and 1B).

The passivation film 108 is selectively removed at the positions overlapped with the source electrodes 106 in the TFT sections, thereby forming contact holes 109 that reach the corresponding source electrodes 106 (see FIG. 1A). The source electrodes 106 are respectively in contact with and electrically connected to overlying pixel electrodes 110 by way of the corresponding contact holes 109. The pixel electrodes 110 are formed on the passivation film 108.

The passivation film 108 and the gate insulating film 103 are selectively removed at the positions overlapped with the gate lines 102 in the gate input terminal sections, where contact holes 111 that reach the corresponding gate lines 102a are formed (see FIG. 1B) The gate lines 102a are respectively contacted with and electrically connected to patterned transparent conductive films 112 by way of the corresponding contact holes 111. The transparent conductive films 112 are formed on the passivation film 108 in the gate input terminal sections.

However, as described above, if the thickness of the gate lines 102a (and the gate electrodes 102) is increased, the level (or height) differences formed by the gate lines 102a (and the gate electrodes 102) are also increased accordingly. Therefore, defects or failures such as disconnection of the other wiring lines formed above the gate lines 102a and/or disclination due to the alignment distortion of the liquid crystal molecules are more likely to occur. For this reason, to eliminate these level differences per se generated by the gate lines 102a (and the gate electrodes 102), a method of burying the gate lines 102a (and the gate electrodes 102) in the grooves or depressions formed in the surface of the insulative plate 101 has ever been developed and proposed.

For example, the Patent Document 1 (the Japanese Non-Examined Patent Publication No. 6-163586 published in 1994) discloses a method of forming a conductive film for gate electrodes and gate lines by plating in the surface of a transparent insulative plate where depressions have been formed. (See the paragraphs 0014 to 0019 and 0024 to 0025, and FIGS. 1 and 2 of the Patent Document 1.) With this method, the surface of a transparent insulative plate is selectively etched using a mask to form depressions therein and then, a ground conductive film is deposited on the mask and in the depressions. Thereafter, a conductive film for gate electrodes and gate lines is deposited on the ground conductive film thus formed by plating and then, the part of the said ground conductive film and the part of the said conductive film for gate electrodes and gate lines are selectively removed along with the mask. This is the known lift-off method. In this way, the remainder of the ground conductive film and that of the conductive film for gate electrodes and gate lines are left in the depressions, resulting in gate electrodes and gate lines (i e., gate bus lines) buried in the depressions.

The Patent Document 2 (the Japanese Non-Examined Patent Publication No. 4-324938 published in 1992) discloses a method of forming a metal film for gate electrodes and gate lines on the surface of an insulative plate where depressions have been formed, by sputtering as one of the known vacuum film formation methods. (See the paragraphs 0019 to 0022 and FIGS. 1 to 3 of this Publication.) With this method, depressions are formed in the surface of an insulative plate and then, a metal film for gate electrodes and gate lines (i.e., for a gate wiring pattern) is formed on the whole surface of the plate by sputtering. Thereafter, the metal film is selectively removed by photolithography and etching to be left in the depressions only. In this way, gate electrodes and gate lines are formed in the depressions.

The Patent Document 3 (the Japanese Non-Examined Patent Publication No. 7-333648 published in 1995) discloses a method of forming a metal film for gate electrodes and gate lines on the surface of an insulative plate where grooves have been formed, by coating a liquid organic metal using known spin coating or the like. (See the paragraphs 0037 to 0044 and FIG. 4 of this Publication.) With this method, after grooves are formed in the surface of an insulative plate, a liquid organic metal is coated on the said surface using spin coating or the like and sintered, thereby forming a metal film for gate electrodes and the gate lines. Subsequently, the metal film thus formed is selectively removed by etching to be left in the grooves, resulting in gate electrodes and gate lines buried in the grooves.

The Patent Document 4 (the Japanese Non-Examined Patent Publication No. 2003-78171 published in 2003) discloses a method of forming metal lines in self-alignment using a minute particle conductive paste. (See Abstract, the paragraphs 0018 to 0025 and FIGS. 1 to 2 of this Publication.) With this method, grooves are formed in a resin layer in accordance with a desired wiring pattern and then, the resin layer is subjected to a hydrophobication process except for the grooves. Alternately, the resin layer is subjected to a hydrophobication process and then, grooves are formed in the resin layer in accordance with a desired wiring pattern. Thereafter, a minute particle conductive paste is coated on the whole surface of the resin layer and sintered, thereby forming metal lines in the grooves in self-alignment. Since the minute particle conductive paste placed on the hydrophobicated region of the resin layer is repelled, the part of the paste placed on the resin layer agglomerates in the grooves in the process where the volume of the paste decreases due to sintering. In this way, the metal lines are formed in self-alignment to have a desired pattern.

However, with the method of forming a conductive film for gate electrodes and gate lines by plating disclosed by the Patent Document 1, the ground conductive film needs to be formed in the depressions of the insulative plate. Moreover, after the formation of the conductive film for gate electrodes and gate lines, a process such as polishing needs to be carried out to make the thickness of the conductive film thus formed uniform. Accordingly, there is a problem that not only the reduction of the count of necessary processes is difficult, but also the equalization of the electric current density distribution in the plating solution (which is important for the plating reaction) is difficult if this method is applied to the insulative plate having a wide area or size. Moreover, another problem that a huge amount of liquid waste needs to be processed occurs.

With the method of forming a metal film for gate electrodes and gate lines by a vacuum film formation method such as sputtering disclosed by the Patent Document 2, it is difficult to form the metal film uniformly in the depressions of the insulative plate. In particular, since the step coverage of sputtering is poor, the thickness of the said metal film is likely to be relatively larger at the top ends of the depressions if the width of the depressions is small. This means that it is difficult for the said metal film to have a uniform thickness oven in the deep inside of the depressions. Accordingly, there is a problem that voids are likely to occur in the depressions and/or in the gate lines buried in the depressions, thereby degrading the chemical resistance and/or the corrosion resistance of the gate lines.

Moreover, if the exposure apparatus is mistakenly positioned in the process of patterning the metal film for gate electrodes and gate lines in such a way as to be aligned with the depressions of the insulative plate using the photolithography method, the said metal film will be left outside the depressions. As a result, with the method of the Patent Document 2, there is another problem that the level difference to be formed on or over the gate electrodes and the gate lines is likely to be larger by the height corresponding to the thickness of the remaining part of the said metal film outside the depressions.

With the method of forming a metal film for gate electrodes and gate lines disclosed by the Patent Document 3 where a liquid organic metal is coated by spin coating or the like and sintered, the above-described problems about the ground conductive film, the liquid waste, and so on in the method of the Patent Document 1 are avoided. This is because a liquid organic metal is used. Besides, the formation of voids, which is the problem of the method of the Patent Document 2, is avoided and at the same time, the metallic material for the gate electrode and the gate lines can be buried in the grooves of the insulative plate. However, an ordinary liquid organic metal has a high sintering temperature, for example, 500° C. or higher. Therefore, there is a problem that usable insulative plates are limited to those having excellent heat resistance, in other words, usable materials for the insulative plate are limited.

Moreover, since an ordinary liquid organic metal contains metallic atoms as organic compounds, the content of the metallic ingredient is low. This means that the volume shrinkage ratio after sintering due to the agglomeration is large. For this reason, even if a person seeks to form metallic wiring lines having a desired thickness in the grooves by the method of the Patent Document 3, another problem that the thickness of the metallic wiring lines varies widely due to the large volume shrinkage ratio will occur.

Furthermore, since an ordinary liquid organic metal contains a lot of nonmetallic ingredients, the gate electrodes and the gate lines formed after sintering contain impurities such as alkalis, sulfur, or the like, on the order of 100 ppm (parts per million). Therefore, the gate input terminals formed at the ends of the respective gate lines contain such the large amount of impurities as above. Unlike the gate electrodes, the gate input terminals are exposed to the moisture or the like existing in their surroundings. Accordingly, with the method of the Patent Document 3, a further problem that the corrosion of the gate input terminals is likely to be triggered by the above-described impurities during the use of the LCD device will occur.

With the method of forming metal lines in self-alignment using a minute particle conductive paste disclosed by the Patent Document 4, agglomeration of the minute particle conductive paste placed on the resin layer is caused by utilizing the volume shrinkage of the said paste due to sintering, thereby collecting the said paste in the grooves. In this way, the metallic wiring lines are formed in self-alignment to have a desired pattern. Therefore, if the interval between the wiring patterns is as large as several tens or several hundreds of micrometers (μm) similar to the wiring patterns used in the LCD device, the minute particle conductive paste may be unintentionally left between the wiring patterns. As a result, there is a possibility that the metallic wiring lines formed in the grooves do not have a desired pattern.

### SUMMARY OF THE INVENTION

The present invention was created in consideration of the above-described problems of the related-art methods.

An object of the present invention is to provide a method of forming buried wiring lines that makes it possible not to limit usable materials for an insulative plate to those having excellent heat resistance and to improve the corrosion resistance of the terminals provided for the buried wiring lines, and a substrate for a display device, and a display device.

Another object of the present invention is to provide a method of forming buried wiring lines that eliminates the extra processes such as the formation of a ground conductive film and the polishing of the conductive film and prevents defects such as voids in the process of burying a wiring material in the grooves formed in the surface of an insulative plate, and that makes it sure to perform the patterning of a wiring material film through less process steps with good thickness accuracy, and a substrate for a display device, and a display device.

Still another object of the present invention is to provide a method of forming buried wiring lines that makes it possible to cope with the demand for further enlargement, higher pixel density, and higher aperture ratio of a display device, and a substrate for a display device, and a display device.

The above objects together with others not specifically mentioned will become clear to those skilled in the art from the following description.

According to the first aspect of the present invention, a method of forming buried wiring lines is provided, which comprises the steps of:

forming a mask with openings corresponding to a desired wiring pattern on a surface of an insulative plate;

selectively etching the surface of the insulative plate using the mask, thereby forming grooves having a plan shape corresponding to the wiring pattern in the surface of the insulative plate;

placing a metallic nanoparticle ink on the whole surface of the insulative plate while leaving the mask in such a way that the grooves are filled with the metallic nanoparticle ink;

heating the metallic nanoparticle ink for its preliminary curing to form a metallic nanoparticle ink film;

selectively removing part of the metallic nanoparticle ink film placed on the mask by detaching the mask, thereby selectively leaving a remainder of the metallic nanoparticle ink film in the grooves; and

heating the remainder of the metallic nanoparticle ink film left in the grooves for its main curing, thereby forming desired buried wiring lines.

The above-described metallic nanoparticle ink is an ink containing minute metallic particles (e.g., minute particles of Au, Ag, or other metal) each of which is covered with a coating agent, where the particles have a diameter on the order of nanometer (nm), in other words, the particles are nanoparticles. As the metallic nanoparticle ink, any one of known metallic nanoparticle inks may be used. It is usual that these minute metallic particles are approximately uniformly dispersed in water or an organic solvent such as xylene, toluene, or an olefinic hydrocarbon with an appropriate dispersing agent. The composite of the minute metallic particles and the water or organic solvent is regulated in such a way as to be a liquid or paste as a whole. Since the minute metallic particles on the order of nm will agglomerate naturally in their as-is status, each of the particles is covered with an appropriate coating agent to prevent the agglomeration.

As a concrete example of the above-described metallic nanoparticle ink, the metallic pastes designed for minute wiring lines “NP series” produced by Harima Chemicals, Inc. are preferably used. These metallic pastes of “NP series” are termed “NANOPASTE”, in other words, “NANOPASTE” is a product name of Harima Chemicals, Inc. However, needless to say, any other ink may be used for the invention if it contains metallic particles the size or diameter of which is on the order of nm and each of which is covered with a coating agent.

With the method of forming buried wiring lines according to the first aspect of the present invention, the buried wiring lines are formed by using the metallic nanoparticle ink. The metallic nanoparticle ink is cured at a low temperature of 100° C. to 200° C. to exhibit sufficiently low electric resistance characteristics. Therefore, the limitation to the material for the insulative plate due to the high sintering temperature as observed in the liquid organic metal used in the prior-art method of the Patent Document 3 is eliminated. This means that usable materials for the insulative plate are not limited to the materials having excellent heat resistance.

Moreover, since the content of the nonmetallic ingredients (i.e., the impurities) of the metallic nanoparticle ink is less than that of the liquid organic metal, the impurities existing in the buried wiring lines formed by using the metallic nanoparticle ink decrease accordingly. In addition, the size or diameter of the metallic nanoparticles contained in the metallic nanoparticle ink is on the order of nm and thus, the metallic nanoparticles are sufficiently small. Therefore, the surface of the metallic nanoparticle ink film (which is formed by curing the metallic nanoparticle ink) has a high flatness and the corrosion rate of said film is suppressed to a low level. Accordingly, the big problem of the metal film formed by using the liquid organic metal (see the Patent Document 3), namely, the corrosion resistance degradation of the terminals provided for the said buried wiring lines, which is triggered by the remaining impurities, can be prevented. This means that the corrosion resistance of the terminals due to the remaining impurities is improved.

Further, the metallic nanoparticle ink has a more content of the metallic ingredient than that of the liquid organic metal and as a result, the volume shrinkage ratio due to the agglomeration is small. Therefore, the thickness dispersion of the metallic nanoparticle ink film formed by sintering the metallic nanoparticle ink is restrained. Accordingly, the buried wiring lines obtained by patterning the metallic nanoparticle ink film have good thickness accuracy.

Furthermore, since the unnecessary part of the metallic nanoparticle ink film is removed by detaching the mask to thereby form the buried wiring lines in the grooves (which means that the lift-off method is used), the detachment of the mask and the patterning of the metallic nanoparticle ink film are completed through a single process. This means that the count of the necessary process steps can be decreased.

In addition, with the method of forming buried wiring lines according to the first aspect of the present invention, as explained above, the metallic nanoparticle ink film is placed over the whole surface of the insulative plate by spin coating or the like to fill the grooves with the metallic nanoparticle ink, where the mask that has been used for the formation of the grooves is left. Thereafter, the metallic nanoparticle ink film is formed by the preliminary curing of the metallic nanoparticle ink and then, the mask is detached to pattern the metallic nanoparticle ink film, resulting in the buried wiring lines having the desired pattern. Therefore, even if the pattern of the wiring lines is minute, defects such as voids do not occur in the process of burying the wiring material (i.e., the metallic nanoparticle ink) in the grooves of the insulative plate, and the extra processes such as the formation of a ground conductive film and the polishing of the conductive film are unnecessary. Besides, the patterning of the wiring material film (i.e., the metallic nanoparticle ink film) is surely conducted.

Further in addition, with the method of forming buried wiring lines according to the first aspect of the present invention, the metallic nanoparticle ink as the wiring material is buried in the grooves of the insulative plate to form the buried wiring lines. Therefore, the demand of extension and miniaturization of wiring lines can be fulfilled while the wiring resistance increase and the level difference increase are suppressed. For this reason, defects or failures such as disconnection of the wiring lines and/or disclination due to the alignment distortion of liquid crystal molecules do not occur. As a result, the demand for further enlargement, higher pixel density, and higher aperture ratio of a display device can be fulfilled.

In a preferred embodiment of the method of forming buried wiring lines according to the first aspect of the invention, between the step of selectively etching the surface of the insulative plate to form the grooves and the step of placing the metallic nanoparticle ink on the whole surface of the insulative plate to fill the grooves with the metallic nanoparticle ink, a step of giving ink-receptivity to the grooves is carried out to increase a surf ace energy of inner surf aces of the grooves. In this embodiment, there is an additional advantage that ink-receptivity is given to the inside surf aces of the grooves and therefore, the filling of the grooves with the metallic nanoparticle ink is surely carried out without voids even if the grooves are minute.

In this embodiment, it is preferred that the surface energy of the inner surfaces of the grooves is higher than a surface tension of the metallic nanoparticle ink.

As the process of giving ink-receptivity to the grooves, any one of the known processes of giving ink-receptivity may be used for the present invention. However, it is preferred that a plasma process to expose the insulative plate to appropriate plasma, or an ultraviolet (UV) process to irradiate UV light to the insulative plate is used.

In another preferred embodiment of the method of forming buried wiring lines according to the first aspect of the invention, metallic nanoparticles of the metallic nanoparticle ink have an average particle size or diameter in a range from 1 nm to 100 nm. This is because the advantages of the low melting point and the low electric resistance after sintering of the metallic nanoparticles are exhibited prominently in this range.

In still another preferred embodiment of the method of forming buried wiring lines according to the first aspect of the invention, metallic nanoparticles of the metallic nanoparticle ink are made of at least one metal selected from the group consisting of Cr, Fe, Ni, Cu, Zn, Ge, Pd, Pt, Ag, In, Sn, Te, Au, B, Mn and Rh.

In still another preferred embodiment of the method of forming buried wiring lines according to the first aspect of the invention, metallic nanoparticles of the metallic nanoparticle ink are made of at least one alloy selected from the group consisting of Cr—Ni, Fe—Si, Fe—Ni, Co—Ni, Fe—Co, Cu—Si, Cu—Sn, Pd—Pt, Ag—Pd, Ag—In, Ag—Au, Ag—Cu, Au—Ge, Au—Sn, Au—Pd, Fe—Pd, Co—Pd, and Ni—Pd.

According to the second aspect of the invention, a substrate for display device is provided; which comprises:

an insulative plate having grooves formed in a surface thereof; and

buried wiring lines formed in the grooves of the insulative plate;

wherein the buried wiring lines are made of cured metallic nanoparticles.

With the substrate for display device according to the second aspect of the invention, the cured metallic nanoparticles for making the buried wiring lines can be provided using the metallic nanoparticle ink used in the method of forming buried wiring lines according to the first aspect of the invention. Therefore, the same advantages as those of the method according to the first aspect of the invention are obtained.

In a preferred embodiment of the substrate for a display device according to the second aspect of the invention, the metallic nanoparticles are made of at least one metal selected from the group consisting of Cr, Fe, Ni, Cu, Zn, Ge, Pd, Pt, Ag, In, Sn, Te, Au, B, Mn and Rh.

In another preferred embodiment of the substrate for a display device according to the second aspect of the invention, the metallic nanoparticles are made of at least one alloy selected from the group consisting of Cr—Ni, Fe—Si, Fe—Ni, Co—Ni, Fe—Co, Cu—Si, Cu—Sn, Pd—Pt, Ag—Pd, Ag—In, Ag—An, Ag—Cu, Au—Ge, Au—Sn, Au—Pd, Fe—Pd, Co—Pd, and Ni—Pd.

In still another preferred embodiment of the substrate for a display device according to the second aspect of the invention, the buried wiring lines are gate lines of a substrate of a LCD device.

According to the third aspect of the invention, a display device is provided; which comprises;

the substrate for display device according to the second aspect of the invention.

With the display device according to the third aspect of the invention, the substrate for display device according to the second aspect of the invention is included and therefore, the same advantages as those of the method according to the first aspect of the invention are obtained.

According to the fourth aspect of the invention, another substrate for display device is provided: which comprises:

an insulative plate having grooves formed in a surface thereof; and

buried wiring lines formed in the grooves of the insulative plate;

wherein the buried wiring lines are formed in the grooves of the insulative plate by using the method of forming buried wiring lines according to the first aspect of the invention.

With the substrate for display device according to the fourth aspect of the invention, since the buried wiring lines are formed in the grooves of the surface of the insulative plate using the method of forming the buried wiring lines according to the first aspect of the invention, the same advantages as those of the method according to the first aspect of the invention are obtained.

In a preferred embodiment of the substrate for a display device according to the fourth aspect of the invention, the buried wiring lines are gate lines of a substrate of a LCD device.

According to the fifth aspect of the invention, a display device is provided; which comprises:

the substrate for display device according to the fourth aspect of the invention.

With the display device according to the fifth aspect of the invention, the substrate for display device according to the fourth aspect of the invention is included and therefore, the same advantages as those of the method according to the first aspect of the invention are obtained.

### BRIEF DESCRIPTION OF THE DRAWINGS

In order that the present invention may be readily carried into effect, it will now be described with reference to the accompanying drawings.

FIG. 1A is a partial cross-sectional view showing the structure of the TFT section of the TFT substrate used in a prior-art LCD device.

FIG. 1B is a partial cross-sectional view showing the structure of the gate input terminal section of the TFT substrate shown in FIG. 1A.

FIG. 1C is a partial cross-sectional view showing the structure of the intersecting section of the gate lines and the drain lines of the TFT substrate shown in FIG. 1A.

FIG. 2 is a partial plan view of a TFT substrate of a LCD device, to which a method of forming buried wiring lines according to an embodiment of the present invention is applied.

FIG. 3A is a partial cross-sectional view along the line IIIA-IIIA in FIG. 2, showing the structure of the TFT section of the TFT substrate shown in FIG. 2.

FIG. 3B is a partial cross-sectional view along the line IIIB-IIIB in FIG. 2, showing the structure of the gate input terminal section of the TFT substrate shown in FIG. 2.

FIG. 3C is a partial cross-sectional view along the line IIIC-IIIC in FIG. 2, showing the structure of the intersecting section of the gate lines and the drain lines of the TFT substrate shown in FIG. 2.

FIGS. 4A and 4F are partial cross-sectional views showing the process steps of the method of forming buried wiring lines according to the embodiment of the present invention, respectively.

FIG. 5 is a schematic partial cross-sectional view showing the structure of the LCD device to which the method of forming buried wiring lines according to the embodiment of the present invention is applied.

### DETAILED DESCRIPTION OF THE PREFERRED EMBODIMENTS

Preferred embodiments of the present invention will be described in detail below while referring to the drawings attached.

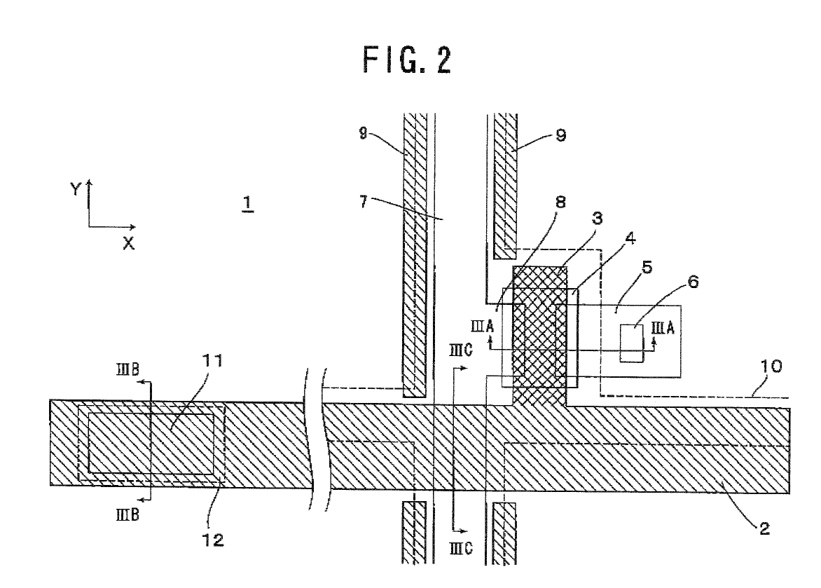

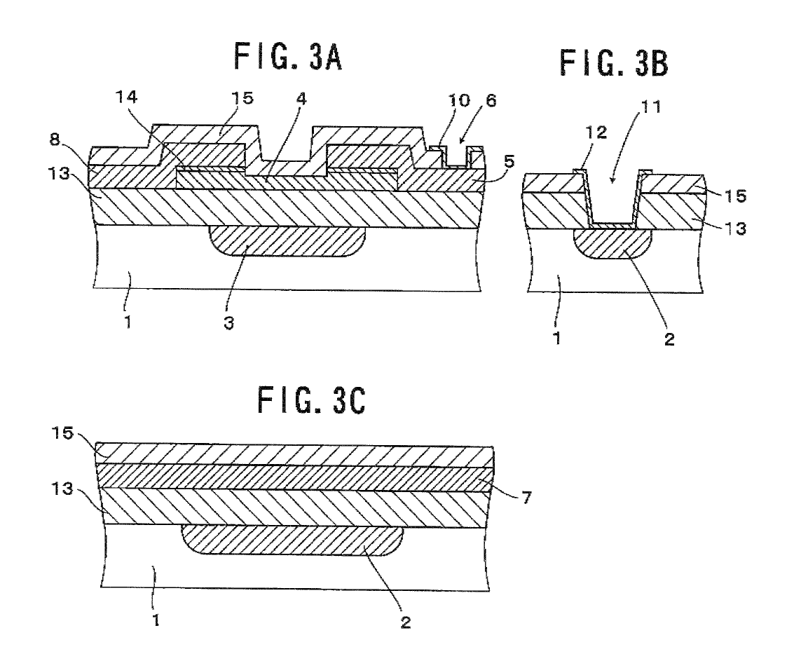

A TFT substrate of a LCD device to which a method of forming buried wiring lines according to an embodiment of the present invention is explained below with reference to FIG. 2 and FIGS. 3A to 3C. These figures show the structures of the TFT section, the gate input terminal section, and the intersecting section of the gate lines and the drain lines, respectively, which correspond to one of the pixels arranged in a matrix array on the TFT substrate, respectively.

As an insulative plate 1, a glass plate is used here. However, any other insulative plate than glass may be used. On the surface of the insulative plate 1, stripe-shaped gate lines 2 extending linearly along the row direction of the matrix (i.e., the X direction in FIG. 2), and gate electrodes 3 connected to the respective gate lines 2 are formed. The gate lines 2 and the gate electrodes 3 are buried in the grooves formed in the surface of the insulative plate 1 to have a desired wiring pattern (i e., a gate wiring pattern). The gate electrodes 3 are formed to protrude along the column direction of the matrix (i.e., the Y direction in FIG. 2) from the respective gate lines 2 to the corresponding TFT sections. The gate lines 2 and the gate electrodes 3 are respectively formed in such a way as to be united with each other using a metal film, where the metal film is formed by sintering a metallic nanoparticle ink. The gate lines 2 and the corresponding gate electrodes 3 are electrically interconnected to each other, respectively. The surfaces of the gate lines 2 and the gate electrodes 3 are approximately in accordance with the surface of the insulative plate 1 and therefore, the whole surface of the plate 1 is kept approximately flat.

As shown in FIGS. 3A to 3C, a transparent gate insulating film 13 is formed on the surface of the insulating plate 1. The gate lines 2, the gate electrodes 3, and the exposed surface of the plate 1 from the gate lines 2 and the gate electrodes 3 are covered with the gate insulating film 13. In the TFT sections, patterned semiconductor films 4 each having an island-like shape are disposed on the gate insulating film 13 at the positions overlapped with the corresponding gate electrodes 3 (see FIG. 3A). A pair of n⁺-type patterned semiconductor films 14 for ohmic contact is disposed at both sides of each semiconductor film 4 except for the region right above the middle part of the corresponding gate electrode 3. A pair of source electrode 5 and a drain electrode 6 is formed on a corresponding one of the pairs of n⁺-type semiconductor films 14.

Drain lines 7 are formed to extend linearly along the column direction of the matrix (the Y direction in FIG. 2) in the form of stripes. The drain lines 7, which are formed by patterning the same conductive film as that for the source and drain electrodes 5 and 8, are respectively united with the drain electrodes 8. The extending direction of the drain lines 7 is perpendicular to the extending direction of the gate lines 2 (the X direction in FIG. 2). The drain electrodes 8 are formed to protrude to the corresponding TFT sections along the X direction perpendicular to the drain lines 7.

A passivation film 15 is formed on the gate insulating film 13 to cover the source and drain electrodes 5 and 8 and the drain lines 7. The passivation film 15 is in contact with the source and drain electrodes 5 and 8, the drain lines 7, and the exposed parts of the gate insulating film 13.

The passivation film 15 is selectively removed at the positions overlapped with the corresponding source electrodes 5 in the TFT sections, thereby forming contact holes 6 that reach the source electrodes 5 respectively. The source electrodes 5 are in contact with and electrically connected to corresponding pixel electrodes 10 by way of the corresponding contact holes 6 (see FIG. 3A). The pixel electrodes 10 are formed by patterning a transparent conductive film to have approximately rectangular plan shapes. The pixel electrodes 10 are disposed on the passivation film 15 in the respective pixel regions defined by the gate lines 2 and the drain lines 7 (see FIG. 2).

Moreover, the passivation film 15 is selectively removed at the positions overlapped with the corresponding gate lines 2 in the gate input terminal sections that are likely to be exposed to the moisture existing in their surroundings, thereby forming contact holes 11 that reach the gate lines 2 respectively (see FIG. 3B). Transparent conductive films 12 are formed on the passivation film 15 in such a way as to cover the inner walls of the respective contact holes 11. Since the conductive films 12 are respectively in contact with the exposed parts of the gate lines 2 in the contact holes 11, the conductive films 12 are electrically connected to the respective gate lines 2. The transparent conductive films 12 are provided for introducing the input signals into the respective gate lines 2. As shown in FIG. 2, the width of each contact hole 11 is set in such a way that the said contact hole 11 does not laterally protrude from the corresponding gate line 2.

Stripe-shaped gate light-shielding films 9 are disposed at both sides of each drain line 7 (see FIG. 2). The gate light-shielding films 9, which are provided for shielding the light entered from the upside of the insulating plate 1, are formed to extend along the drain lines 7.

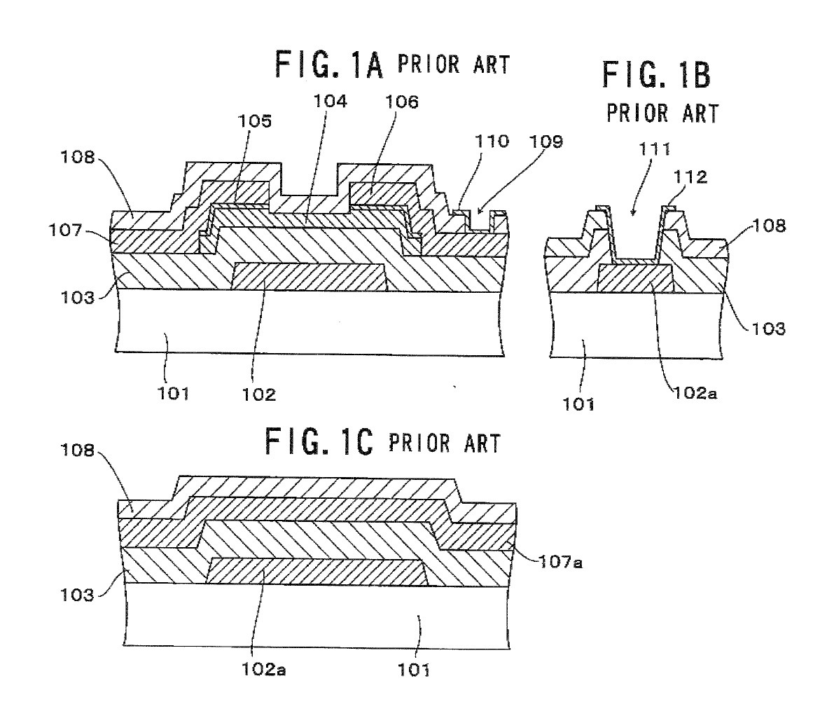

Since the gate electrodes 3 and the corresponding gate lines 2 are buried in the respective grooves of the surface of the insulative plate 1, the whole surface of the plate 1 is kept at approximately flat. As a result, the level differences in the TFT sections and the gate input terminal sections are less than those of the prior-art LCD device shown in FIGS. 1A to 1C (see FIGS. 3A and 3B). Since no level difference is generated in the interconnection sections of the gate lines 2 and the drain lines 7, the drain lines 7 extend in a flat plane (see FIG. 3C).

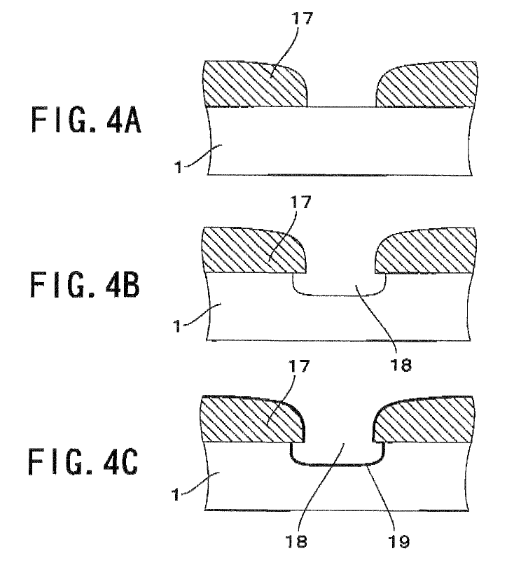

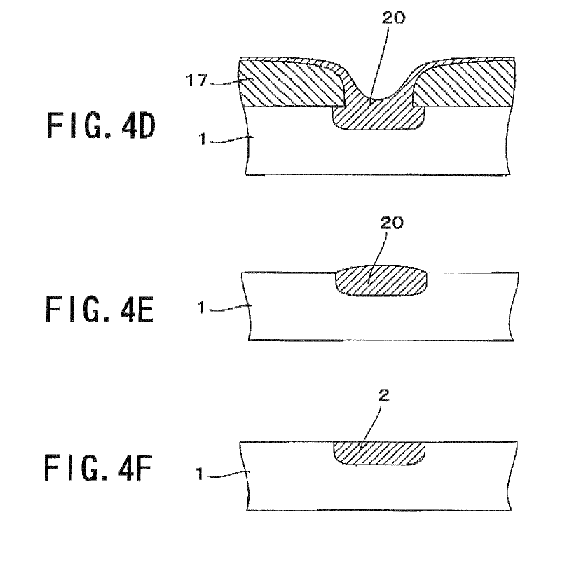

Next, the process steps of forming the gate lines 2 and the gate electrodes 3 of the TFT substrate shown in FIG. 2 and FIGS. 3A to 3C using the method of forming buried wiring lines according to the embodiment of the invention will be explained below with reference to FIGS. 4A to 4F.

First, a positive-type photoresist is coated on the whole surface of the insulative plate (here, the glass plate) 1 to form a photoresist film (not shown). Next, the part of the photoresist film that will be a pattern for the gate electrodes 2 and the gate lines 3 (i.e., the gate wiring pattern) is selectively exposed to light and developed using the known photolithography technique, thereby forming a mask 17 (see FIG. 4A). The mask 17 thus formed has openings corresponding to the desired gate wiring pattern. In other words, the openings of the mask 17 are such that grooves are formed to have a reversed pattern of the desired gate wiring pattern.

Next, the surface of the insulative plate 1 is selectively etched by wet etching using the mask 17, thereby forming grooves 18 in the surface of the plate 1 (see FIG. 4B). These grooves 18 have a reversed pattern of the desired gate wiring pattern. The depth of the grooves 18, i.e., the etched depth, is set at 1 μm, for example. In this etching process, an isotropic wet etching method having a high etch rate is used and therefore, the etching time can be reduced. However, because of the use of the wet etching, the insulative plate 1 is etched not only along the vertical direction (i.e., the downward direction in FIG. 4E) but also the lateral direction (i.e., the left and right directions in FIG. 4B) at approximately equal etch rates. As a result, the width of the grooves 18 is slightly larger than the width of the openings of the mask 17. For this reason, undercut regions are formed in the plate 1 at the positions right below the mask 17. Buffered hydrogen fluoride (HF) may be used as the etching solution for this etching process, for example.

The grooves 18 may be formed by etching the insulative plate 1 anisotropically using a dry etching method. In this case, the formation of the above-described undercut regions can be suppressed.

If the depth of the grooves 18 needs to be large, in other words, if the etching time needs to be prolonged to increase the thickness of the gate electrodes 3 and the gate lines 2, a metal mask having better endurance (which is made of a metal, such as Cr) may be used instead of the mask 17 made of photoresist.

Subsequently, the insulative plate 1 where the mask 17 and the grooves 18 have been formed is exposed to predetermined plasma, thereby giving a “plasma treatment” to the whole surface of the plate 1. This plasma treatment is performed to increase the “surface energy” of the inner surfaces of the grooves 18, thereby enhancing the adhesion property between the inner surfaces of the grooves 18 of the plate 1 and a metallic nanoparticle ink that will be coated thereon in a later process. This plasma treatment serves as a pretreatment for coating the metallic nanoparticle ink. Here, the “surface energy” means the surface free energy as a free energy component of the total energy any surface has, which is equal to the surface tension of the metallic nanoparticle ink. Due to this plasma treatment, a layer whose surface energy has been increased, that is, an ink-receptivity processed layer 19 is formed (see FIG. 4C). The ink-receptivity processed layer 19 covers the whole surface of the mask 17 and the whole inner surfaces of the grooves 18 exposed from the mask 17. This plasma treatment may be termed the “ink-receptivity process” because the ink-receptivity processed layer 19 is formed by the said plasma treatment. As the plasma gas for the said plasma treatment, Ar or He may be used, for example.

As another ink-receptivity process, an “ultraviolet (UV) treatment” may be used for this purpose. In this case, UV light of a predetermined wavelength is irradiated to the insulative plate 1 where the mask 17 and the grooves 18 have been formed.

Next, by spin coating or the like, a metallic nanoparticle ink is coated on the whole surface of the insulative plate 1 to which the ink-receptivity process has been applied, thereby forming a metallic nanoparticle ink film 20 (see FIG. 4D). At this time, the ink-receptivity processed layer 19 is formed on the inner surfaces of the grooves 18 of the plate 1 and therefore, the surface energy of the inner surfaces of the grooves 18 are larger than the surface tension of the metallic nanoparticle ink. Accordingly, the metallic nanoparticle ink enters smoothly the insides of the grooves 18 and as a result, the grooves 18 and the openings of the mask 17 are surely filled with the metallic nanoparticle ink without generating voids.

When the metallic nanoparticle ink is coated to cover the surface of the insulative plate 1, the thickness of the metallic nanoparticle ink film 20 at the positions right above the grooves 18 is adjusted in such a way as to be slightly larger than the depth of the grooves 18. This is based on the consideration for the fact that the volume of the metallic nanoparticle ink film 20 is reduced (i.e., the film reduction) in the subsequent sintering process. Such the thickness of the film 20 as above is easily realized by adjusting the coating amount of the metallic nanoparticle ink, the rotation speed, and so on, in the spin coating process.

Because wet etching is used in the process of forming the grooves in the surface of the insulative plate 18, the undercut regions are formed below the mask 17 due to the isotropic etching action. However, the metallic nanoparticle ink is coated over the surface of the plate 1 to cover the mask 17 by the spin coating method, thereby forming the metallic nanoparticle ink film 20 in this embodiment. Therefore, the undercut regions can be surely filled with the metallic nanoparticle ink.

It is preferred that the metallic nanoparticles contained in the metallic nanoparticle ink have an average particle size or diameter in a range from 1 nm to 100 nm. This is because the advantages of the low melting point and the low electric resistance after sintering of the metallic nanoparticles are exhibited prominently in this range. Here, the “average particle size” denotes the typical size or diameter of the metallic nanoparticles contained in the metallic nanoparticle ink. In addition, the “particle size” denotes the geometric diameter or size of the individual metallic nanoparticle.

The concrete examples of the metallic nanoparticles contained in the metallic nanoparticle ink are shown below. It is preferred that the metallic nanoparticles are made of a metal selected from the group consisting of Cr, Fe, Ni, Cu, Zn, Ge, Pd, Pt, Ag, In, Sn, Te, Au, B, Mn and Rh, or made of alloy of at least two metals selected from the same group. It is preferred that the metallic nanoparticles are made of at least one alloy selected from the group consisting of Cr—Ni, Fe—Si, Fe—Ni, Co—Ni, Fe—Co, Cu—Si, Cu—Sn, Pd—Pt, Ag—Pd, Ag—In, Ag—Au, Ag—Cu, Au—Ge, Au—Sn, Au—Pd, Fe—Pd, Co—Pd, and Ni—Pd.

The metallic nanoparticles contained in the metallic nanoparticle ink are dispersed approximately uniformly in water or an organic solvent such as xylene, toluene, or an olefinic hydrocarbon without agglomeration. The composite of the metallic particles and the water or organic solvent is regulated in such a way as to be ink (or liquid or paste) as a whole. To disperse the metallic nanoparticles in the water or organic solvent, an appropriate dispersing agent is added. Moreover, to prevent the natural agglomeration of the metallic nanoparticles, each of the nanoparticles is covered with an appropriate coating agent.

Subsequently, the insulative plate 1 on which the metallic nanoparticle ink film 20 has been formed is heated at 100° C. for a predetermined time, thereby performing the preliminary sintering of the film 20. This is to remove the organic solvent contained in the film 20 at a certain extent and to preliminarily cure the film 20. It is sufficient that the “preliminary sintering (preliminary curing)” of the metallic nanoparticle ink film 20 is performed to an extent or level where the selective removal of the part of the film 20 placed on the mask 17 is carried out smoothly in the next step of selectively removing the film 20 along with the mask 17. The temperature of the preliminary sintering (preliminary curing) is adjusted appropriately according to the type or sort of the metallic nanoparticle ink used.

After the preliminary curing of the metallic nanoparticle ink film 20 is completed, the mask 17 is detached from the insulative plate 1. As a result, the part of the film 20 attached to the surface of the mask 17 is removed along with the mask 17 and at the same time, the remainder of the film 20 is left only in the grooves 18 (see FIG. 4E). In this stage, the remainder of the film 20 existing in the grooves 18 protrudes slightly from the surface of the plate 1.

Finally, the insulative plate 1 where the remainder of the metallic nanoparticle ink film 20 thus preliminarily cured has been left in the grooves 18 is heated again at a higher temperature in the range from 150° C. to 200° C. for a predetermined time, thereby performing the main sintering (main curing) of the film 20 During the process of the main sintering (main curing), the water or organic solvent and the dispersing agent existing in the remainder of the film 20 are removed and at the same time, the coating agent covering the respective metallic nanoparticles is vaporized so that the metallic nanoparticles are contacted with each other and finally cured. As a result, the metallic nanoparticle ink film 20 is turned to a metal film having electrical conductivity. The metal film thus formed serves as the buried wiring lines in the grooves 18, in other words, the gate lines 2 (see FIG. 4F). In addition, the temperature of the main sintering (main curing) is adjusted appropriately according to the type or sort of the metallic nanoparticle ink used.

Since the coating agent, the water or organic solvent, and the dispersing agent existing in the metallic nanoparticle ink film 20 are removed in the step of the main sintering (main curing), the volume reduction of the remaining part of the said film 20 (i.e., film reduction) in the grooves 18 occurs. However, the amount of the possible volume reduction of the film 20 has been calculated in advance and then, the thickness of the film 20 has been intentionally set at a slightly larger value than the right one where the top of the film 20 will be flat. Accordingly, as shown in FIG. 4F, the surface of the insulative plate 1 and that of the gate lines 2 thus formed are in the same plane, in other words, they are flat.

Although not illustrated, simultaneously with the formation of the gate lines 2, the gate electrodes 3 are formed in such a way as to be buried in the grooves 18 also.

As explained above, with the method of forming buried wiring lines according to the embodiment of the present invention, the buried wiring lines, that is, the buried gate lines 2 (and the buried gate electrodes 3) are formed by using the metallic nanoparticle ink. The metallic nanoparticle ink used here exhibits its sufficiently low electric resistance characteristics by the curing process at a low temperature of 100° C. to 200° C. Therefore, the limitation to the material for the insulative plate 1 due to the high sintering temperature as observed in the liquid organic metal used in the prior-art method of the Patent Document 3 is eliminated. This means that usable materials for the insulative plate 1 are not limited to the materials having excellent heat resistance.

Moreover, since the content of the nonmetallic ingredients (i.e., the impurities) of the metallic nanoparticle ink film 20 is less than that of the liquid organic metal, the amount of the impurities existing in the buried gate lines 2 (and the buried gate electrodes 3) formed by the metallic nanoparticle ink decreases accordingly. In addition, the diameter of the metallic nanoparticles contained in the metallic nanoparticle ink is on the order of nm and thus, the surface of the metallic nanoparticle ink film 20, which is formed by curing the metallic nanoparticle ink, has a high flatness. It is general that the higher the flatness of a metal film, the higher the corrosion resistance of the metal film, and that the lower the impurity concentration of a metal film, the higher the corrosion resistance of the metal film. Therefore, the big problem of the metal film formed by using the liquid organic metal (see the Patent Document 3), namely, the corrosion resistance degradation of the gate input terminal sections provided for the respective gate lines 2, which is triggered by the remaining impurities, can be prevented. This means that the corrosion resistance of the gate input terminal sections due to the remaining impurities in the metal film is improved.

Further, the volume shrinkage ratio of the metallic nanoparticle ink due to the agglomeration after sintering is smaller than that of the liquid organic metal. Therefore, the thickness dispersion of the metallic nanoparticle ink film 20 formed by sintering the said metallic nanoparticle ink is restrained. Accordingly, the buried wiring lines, i.e., the buried gate lines 2 (and the buried gate electrodes 3) obtained by patterning the said film 20 have good thickness accuracy.

Furthermore, the unnecessary part of the metallic nanoparticle ink film 20 is removed by detaching the mask 17 used to form the grooves 18, thereby forming the buried gate lines 2 (and the buried gate electrodes 3) in the grooves 18 (which means that the lift-off method is used). Therefore, the detachment of the mask 17 and the patterning of the said film 20 are completed through a single process. This means that the count of the necessary process steps can be decreased.

In addition, the metallic nanoparticle ink is placed over the whole surface of the insulative plate 1 by spin coating or the like while the mask 17 which has been used for forming the grooves 18 is left, thereby filling the grooves 18 with the said ink. Thereafter, the metallic nanoparticle ink film 20 is formed by the preliminary curing of the metallic nanoparticle ink and then, the mask 17 is detached to pattern the said film 20. Further, the remaining part of the film 20 is subjected to the main curing process to form the buried gate lines 2 (and the buried gate electrodes 3) having the desired pattern. Accordingly, even if the pattern of the gate lines 2 is minute, defects such as voids do not occur in the process of burying the wiring material (i.e., the metallic nanoparticle ink) in the grooves 18 of the insulative plate 1, and the extra processes such as the formation of a ground conductive film and the polishing of the conductive film are unnecessary. Besides, the patterning of the wiring material film (i.e., the metallic nanoparticle ink film 20) is surely conducted.

Furthermore, since the metallic nanoparticle ink as the wiring material is buried in the grooves 18 of the insulative plate 1 to form the buried gate lines 2 (and the buried gate electrodes 3), the demand of extension and miniaturization of the gate lines 2 can be fulfilled while the wiring resistance increase and the level difference increase are suppressed. For this reason, defects or failures such as disconnection of the wiring lines and/or disclination due to the alignment distortion of liquid crystal molecules do not occur. As a result, the demand for further enlargement, higher pixel density, and higher aperture ratio of a display device can be fulfilled.

When the formation of the buried gate lines 2 and the buried gate electrodes 3 is finished through the above-described process steps, as shown in FIG. 4F, the following process steps are carried out subsequently to complete the TFTs.

After the formation of the burled gate lines 2 and the buried gate electrodes 3 is finished, for example, a SiN film is formed on the whole surface of the insulative substrate 1 to have a thickness of approximately 300 to 500 nm by plasma CVD (Chemical Vapor Deposition), forming the gate insulating film 13. Then, an intrinsic amorphous silicon (a-Si) film is formed on the gate insulating film 13 to have a thickness of approximately 200 nm. On the intrinsic a-Si film thus formed, an n⁺-type a-Si film doped with phosphorus (P) is formed to have a thickness of approximately 50 nm. These two a-Si films are formed by plasma CVD. Thereafter, the n⁺-type a-Si film and the intrinsic a-Si film are selectively removed by dry etching successively using a resist film with a predetermined pattern as a mask. Thus, the island-shaped intrinsic semiconductor films 4 are formed on the gate insulating film 13, and the island-shaped n⁺-type semiconductor film for ohmic contact are formed on the respective semiconductor films 4. A polysilicon film may be used for the semiconductor films 4 instead of the a-Si film.

Next, a metal film (e.g., a Mo film) is deposited on the whole surface of the insulative plate 1 to have a thickness of approximately 300 nm by sputtering. This metal film is placed on the gate insulating film 13. Thereafter, this metal film is selectively etched using a resist film (not shown) with a predetermined pattern, thereby forming the source electrodes 5, the drain electrodes 8, and the drain lines 7.

Next, using the source and drain electrodes 5 and 8 as a mask, the island-shaped n⁺-type semiconductor films are selectively etched. Thus, gaps are respectively formed at the middle positions of the n⁺-type semiconductor films to penetrate through the same, resulting in the pairs of n⁺-type semiconductor films 14. At the same time, shallow depressions are respectively formed in the surfaces of the intrinsic semiconductor films 4 at their middle positions just below the gaps. Channel regions are respectively generated in the insides of the intrinsic semiconductor films 4 at the positions right below the depressions. In this way, TFTs serving as the switching elements are respectively formed in the vicinities of the intersections of the gate lines 2 and the drain lines 7.

Next, for example, a SiN film is formed on the whole surface of the insulative plate 1 to have a thickness of approximately 150 to 200 nm by plasma CVD, thereby forming the passivation film 15. Thereafter, using a resist (not shown) with a predetermined pattern as a mask, the passivation film 15 thus formed is selectively removed at the predetermined positions that overlap with the source electrodes 5 in the TFT sections. At the same time, the passivation film 15 and the gate insulating film 13 are selectively removed at the predetermined positions that overlap with the gate lines 2 in the gate input terminal sections. In this way, the contact holes reaching the corresponding source electrodes 5 and the contact holes 11 reaching the corresponding gate lines 2 are formed (see FIGS. 3A and 3B).

Following this, for example, an ITO (Indium Tin Oxide) film is formed on the whole surface of the insulative plate 1 to have a thickness of approximately 50 nm by sputtering. Then, the ITO film is selectively removed using a resist (not shown) with a predetermined pattern as a mask, thereby forming the pixel electrodes 10 and the patterned transparent conductive films 12. The pixel electrodes 10, which are placed on the passivation film 15, are in contact with the source electrodes 5 by way of the contact holes 6, respectively (see FIG. 3A). The transparent conductive films 12, which are placed on the passivation film 15, are in contact with the gate lines 2 by way of the contact holes 11, respectively (see FIG. 38).

Through the above-described process steps, the TFTs, the pixel electrodes 10, the gate lines 2, and the drain lines 7 are completed, as shown in FIG. 2 and FIGS. 3A to 3C.

As explained above, with the method of fabricating a TFT substrate for a LCD device according to the embodiment of the invention, the buried gate lines 2 (i.e., buried wiring lines) are respectively formed in the grooves 18 of the insulative plate 1 using the above-described method of forming buried wiring lines according to the embodiment of the invention. Therefore, the same advantages as those of the method of forming buried wiring lines according to the embodiment of the invention are obtained.

Moreover, an opposite substrate on which a color filter, a black matrix, and so on are formed is fabricated by a known method and is coupled with the TFT substrate fabricated in such the manner as above. A liquid crystal layer is sandwiched between the TFT substrate and the opposite substrate. As a result, a LCD device is fabricated.

With the LCD device thus fabricated, the gate lines 2 and the gate electrodes 3 (i.e., the buried wiring lines) on the TFT substrate are formed by using the above-described method of forming buried wiring lines according to the embodiment of the invention. Therefore, the same advantages as those of method of forming buried wiring lines according to the embodiment of the invention are obtained.

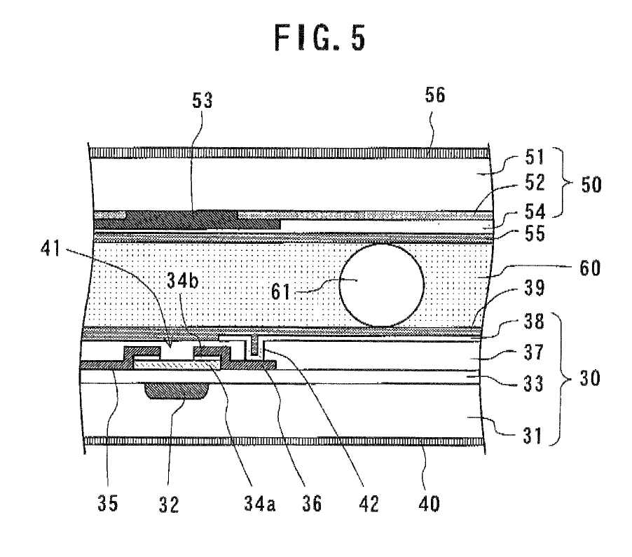

FIG. 5 shows an example of the structure of the LCD device thus fabricated, where the structure corresponding to one of the pixels is shown. The structure of the LCD device corresponding to the pixel is explained below for simplification.

As shown in FIG. 5, this LCD device comprises the TFT substrate 30, the opposite substrate 50 coupled with the TFT substrate 30, and the liquid crystal layer 60 formed between the TFT substrate 30 and the opposite substrate 50. The alignment direction of the liquid crystal molecules in the liquid crystal layer 60 is changed to control the amount of the transmitted light in each pixel, thereby displaying desired characters, images, and so on.

Regarding the TFT substrate 30, a gate electrode 32 (the gate electrode 3) and a gate line (the gate electrode 2) are formed in the grooves of the surface of a transparent glass plate 31 (the insulative plate 1). The gate electrode 32 and the gate line are buried in the grooves. A gate insulating film 33 (the gate insulating film 13) is formed on the surface of the glass plate 31 to cover the gate electrode 32 and the gate line. An island-shaped intrinsic a-Si film 34a (the intrinsic a-Si film 4) is formed on the gate insulating film 33 to overlap with the underlying gate electrode 32. A pair of n⁺-type a-Si films 34b (the pair of n⁺-type a-Si films 14) for ohmic contact is formed on the intrinsic a-Si film 34a at each side thereof. A drain electrode 35 and a source electrode 36 (the drain electrode 8 and the source electrode 5) are formed on the gate insulating film 33 at each side of the a-Si film 34a to overlap respectively with the pair of n⁺-type a-Si films 34b, forming a TFT 41. A passivation film 37 (the passivation film 15) is formed on the gate insulating film 33 to cover the TFT 41. A pixel electrode 38 (the pixel electrode 10) is formed on the passivation film 37 to be contacted with the source electrode 36 by way of a contact hole 42 penetrating through the passivation film 37. An alignment film 39 is formed on the passivation film 37 to cover the pixel electrode 38.

Regarding the color filter substrate 50, a black matrix 53 and color layers 52 constituting a color filter are formed on the surface of a transparent glass plate 51. A common or opposite electrode 54 is formed to cover the black matrix 53 and the color layers 52. An alignment film 55 is formed on the common or opposite electrode 54 to cover the same.

A polarizer plate 40 is attached to the back (outer surface) of the glass plate 31. A polarizer plate 56 is attached to the back (outer surface) of the glass plate 51. Spherical spacers 61 are dispersed in the liquid crystal layer 60.

Needless to say, the LCD device may have any other structure than that shown here.

### Variations

The above-described embodiment is a preferred example of the present invention. Therefore, needless to say, the present invention is not limited to the embodiment and any modification is applicable to it.

For example, in the above-described embodiment, the metallic nanoparticle ink is coated on the mask after the surface energy of the insulative plate has been enlarged to form the ink-receptivity processed layer. However, if the surface energy of the insulative plate is larger than the surface tension of the metallic nanoparticle ink used, the metallic nanoparticle ink may be coated on the mask without enlarging the surface energy of the insulative plate (in other words, without the ink-receptivity process).

As the metallic nanoparticle for the metallic nanoparticle ink, any other nanoparticle than that shown in the above-described embodiment may be used if it is an electrically conductive particle made of a metal or alloy on the order of nanometer.

In the above-described embodiment, the present invention is applied to the gate lines formed on the TFT substrate of the LCD device. However, the invention is not limited to this. The invention is applicable to any other type of display devices such as an organic EL display device, a plasma display device, and so on, if it comprises buried wiring lines formed in the surface of an insulative plate.

For example, if the present invention is applied to an organic EL display device, TFTs including the buried gate electrodes and buried gate lines are formed on a substrate serving as an anode and then, organic EL layers for Red, Green, and Blue colors are selectively formed in sequence on the same substrate as a color filter.

While the preferred forms of the present invention have been described, it is to be understood that modifications will be apparent to those skilled in the art without departing from the spirit of the invention. The scope of the present invention, therefore, is to be determined solely by the following claims.

What is claimed is:

1. A method of forming buried wiring lines, the method comprising the steps of:
forming a mask with openings corresponding to a desired wiring pattern on a surface of an insulative plate;
selectively etching the surface of the plate using the mask, thereby forming grooves having a plan shape corresponding to the wiring pattern in the surface of the insulative plate:
placing a metallic nanoparticle ink on the whole surface of the insulative plate while leaving the mask in such a way that the grooves are filled with the metallic nanoparticle ink;
heating the metallic nanoparticle ink for its preliminary curing to form a metallic nanoparticle ink film;
selectively removing part of the metallic nanoparticle ink film placed on the mask by detaching the mask, thereby selectively leaving a remainder of the metallic nanoparticle ink film in the grooves; and
heating the remainder of the metallic nanoparticle ink film left in the grooves for its main caring, thereby forming desired buried wiring lines.

2. The method according to claim 1, wherein between the step of selectively etching the surface of the insulative plate to form the grooves and the step of placing the metallic nanoparticle ink on the whole surface of the insulative plate to fill the grooves with the metallic nanoparticle ink, a step of giving ink-receptivity to the grooves is carried out to increase a surface energy of inner surfaces of the grooves.

3. The method according to claim 2, wherein a plasma process to expose the insulative plate to plasma, or an ultraviolet (UV) process to irradiate UV light to the insulative plate is used in the step of giving ink-receptivity to the grooves.

4. The method according to claim 2, wherein the surface energy of the inner surfaces of the grooves is higher than a surface tension of the metallic nanoparticle ink.

5. The method according to claim 1, wherein metallic nanoparticles of the metallic nanoparticle ink have an average diameter in a range from 1 nm to 100 nm.

6. A substrate for a display device comprising:
an insulative plate having grooves formed in a surface thereof; and
buried wiring lines formed in the grooves of the insulative plate;
wherein the buried wiring lines are formed in the grooves of the insulative plate by using the method of forming buried wiring lines according to claim 1.

7. A display device comprising:
the substrate for display device according to claim 6.
